(19) United States
(12) Patent Application Publication
(10) Pub. No.: US 2020/0065545 A1
(43) Pub. Date: Feb. 27, 2020

(54) BIOMETRIC SENSOR AND DISPLAY DEVICE HAVING SAME

(71) Applicant: POINT ENGINEERING CO., LTD., Asan (KR)

(72) Inventors: Bum Mo AHN, Suwon (KR); Seung Ho PARK, Hwaseong (KR); Sung Hyun BYUN, Hwaseong (KR)

(21) Appl. No.: 16/546,108

(22) Filed: Aug. 20, 2019

(30) Foreign Application Priority Data
Aug. 22, 2018 (KR) 10-2018-0097747

(51) Int. Cl. G06K 9/00; H01L 27/146

(52) U.S. Cl. CPC G06K 9/0004; H01L 27/14625; H01L 27/14678

(57) ABSTRACT

Disclosed is a biometric sensor capable of reliably obtaining a biometric image optically. Further disclosed is a display device including the biometric sensor. The biometric sensor includes a photo-detector and an anodic oxide film. The anodic oxide film is provided with a through hole vertically extending through the anodic oxide film from an upper surface to a lower surface, having a larger width than pores formed in the anodic oxide film during anodic oxidation, and providing an optical path leading to the photo-detector.

### CROSS REFERENCE TO RELATED APPLICATION

The present application claims priority to Korean Patent Application No. 10-2018-0097747, filed Aug. 22, 2018, the entire contents of which is incorporated herein for all purposes by this reference.

### BACKGROUND OF THE INVENTION

### 1. Field of the Invention

The present invention relates to a biometric sensor and a display device including the biometric sensor.

### 2. Description of the Related Art

Biometrics technology is a method of identifying or authenticating a person by reading physical characteristics with a sensor and is also referred to as bio-recognition technology or biometrics. Biometric technology includes face recognition using faces and thermal images, iris recognition, vein recognition, fingerprint recognition, retina recognition, hand geometry recognition, etc.

Fingerprint sensor technologies for detecting a biometric characteristic such as a fingerprint are segmented into two main categories: capacitive and optical. A capacitive fingerprint sensor recognizes a fingerprint by measuring the capacitance at different points on a scanner with a semiconductor device highly sensitive to a voltage and a current. Such a capacitive fingerprint sensor is reportedly vulnerable to fake fingerprints and has relatively high read errors.

An optical fingerprint sensor is composed of a light source and an image sensors. The optical fingerprint scanner recognizes a fingerprint in such a manner that the image sensor detects light first emitted from the light source and then reflected from a target fingerprint. The optical fingerprint sensor is advantageous over the capacitive fingerprint sensor in that it is less vulnerable to spoofing and masquerade attacks but has a problem that it is difficult to be miniaturized due to the use of a large optical component such as a reflection mirror or a lens. In addition, when the distance between a fingerprint and an image sensor is great, a light ray reflected from an adjacent fingerprint is easy to enter the image sensor, resulting in mixing of light rays reflected from different fingerprints. Thus, it is difficult to obtain a clear fingerprint image.

In order to solve these problems, techniques have been developed in which a collimator for directing a reflection light ray in a substantially vertical direction toward a photo-detector is disposed above the photo-detector. Korean Patent Application Publication No. 2016-0144453 (hereinafter referred to as Related Art 1) discloses a collimator formed of a bundle of optical fibers and a collimator formed of a stack of metal plates alternately stacked. However, it is difficult to manufacture a bundle of optical fibers having a uniform height. Therefore, the collimator made from a bundle of optical fibers is likely to be uneven in height. On the other hand, in the case of a collimator made from a stack of metal plates, it is not common that there is a local high difference in the uppermost metal plate between a lengthwise direction and a widthwise direction.

On the other hand, Korean Patent Application Publication No. 2016-0048643 (hereinafter referred to Related Art 2) discloses a collimator made from a wafer having through holes. In the case of Related Art 2, since it is difficult to form deep vertical through holes, the vertical through holes formed in a wafer have a small aspect ratio. Therefore, light that is obliquely incident on the periphery of each through hole is refracted and the refracted light is incident on a photo-detector. That is, light mixing occurs. Therefore, it is difficult to obtain clear image information of a biometric sample disposed immediately above the photo-detector.

### DOCUMENT OF RELATED ART

Patent Document

(Patent Document 1) Korean Patent Application Publication No. 2016-0144453

(Patent Document 2) Korean Patent Application Publication No. 2016-0048643

### SUMMARY OF THE INVENTION

Accordingly, the present invention has been made to solve the above problems of the related arts, and an object of the present invention is to provide a biometric sensor capable of reliably acquiring a biometric image optically and a display device including the biometric sensor.

To achieve one object of the present invention, there is provided a biometric sensor including: a photo-detector; and an anodic oxide film provided with a through hole vertically extending through the anodic oxide film from an upper surface to a lower surface, having a larger width than pores formed in the anodic oxide film during anodic oxidation, and providing an optical path leading to the photo-detector.

The anodic oxide film may include a light-absorbing material, thereby directing the light toward the photo-detector only through the through hole.

To achieve the object of the present invention, there is a display device including: a display panel having pixels; and a biometric sensor including a photo-detector and a collimator, wherein the collimator includes an anodic oxide film provided with a through hole vertically extending through the anodic oxide film from an upper surface to a lower surface, having a larger width than pores formed in the anodic oxide film during anodic oxidation, and providing an optical path leading to the photo-detector.

The through hole may be positioned between the pixels and under the display panel.

The biometric sensor further may include a light source provided on a side surface of the biometric sensor to emit an emission light ray.

The light source may be a light emitting diode (LED).

In the display device, a biometric sampling region in which a light ray can be incident on the bottom of one through hole does not overlap with a biometric reflection region in which a light ray can be incident on the bottom of an adjacent through hole.

The through hole may have a rectangular cross-sectional shape.

The photo-detectors and the through holes may be in a one-to-multiple correspondence relationship.

The biometric sensor may be a fingerprint recognition sensor.

The anodic oxide film may be disposed on the photo-detector.

Further, the anodic oxide film may be disposed under the photo-detector.

To achieve the object of the present invention, there is a display device including: a front cover made of a light-transmitting material; a display panel disposed under the front cover and provided with pixels; and a biometric sensor disposed under the display panel, in which the biometric sensor includes a photo-detector and a collimator disposed on the photo-detector and configured to direct a reflection light ray toward the photo-detector, and wherein the collimator includes an anodic oxide film provided with a through hole vertically extending through the anodic oxide film from an upper surface to a lower surface, having a larger width than pores formed in the anodic oxide film during anodic oxidation, and providing an optical path leading to the photo-detector.

The biometric sensor further may include a light source provided on a side surface of the biometric sensor to emit an emission light ray.

As described above, the biometric sensor and the display device having the biometric sensor according to the present invention can reliably obtain biometric image information from which is the basis on which a biometric image is optically acquired.

### BRIEF DESCRIPTION OF THE DRAWINGS

FIG. 1 is an exploded perspective view of a biometric sensor according to a first preferred embodiment of the present invention and a display device including the biometric sensor;

FIG. 2 is a plan view of the biometric sensor according to the first preferred embodiment of the present invention and the display device including the biometric sensor;

FIG. 3 is a cross-sectional view taken along a line A-A′ of FIG. 2;

FIG. 4 is a plan view illustrating the biometric sensor according to the first preferred embodiment of the present invention, the display device including the biometric sensor, and a light source included in the display device;

FIG. 5 is a diagram illustrating the biometric sensor according to the first preferred embodiment of the present invention and the display device including the biometric sensor;

FIG. 6A, FIG. 6B, and FIG. 6C are diagrams illustrating various forms of an anodic oxide film included in the biometric sensor according to the first preferred embodiment of the present invention and in the display device including the biometric sensor;

FIGS. 7A through 7D are diagrams illustrating various forms of a through hole included in the biometric sensor according to the first preferred embodiment of the present invention and in the display device including the biometric sensor;

FIGS. 8A and 8B are plan views illustrating biometric sensors according to second and third embodiments of the present inventions and the display devices including the respective biometric sensors;

FIG. 9 is a cross-sectional view taken along a line A-A′ of FIGS. 8A and 8B;

FIG. 10 is a diagram illustrating emission light rays and reflection light rays involved in the biometric sensors according to second and third embodiments of the present inventions and in the display device including the respective biometric sensors;

FIG. 11 is a diagram illustrating a digitized form of an overall biometric image generated by photo-detectors in a biometric sensor device according to each of the second and third embodiments of the present inventions and in each of the display devices including the respective biometric sensors;

FIG. 12 is a diagram illustrating a biometric sensor according to a fourth preferred embodiment of the present invention and a display device including the biometric sensor;

FIG. 13 is a diagram illustrating the structure of a biometric sensor package according to one embodiment of the present invention; and

FIG. 14 is a diagram illustrating an incidence path of a reflection light ray according to a preferred embodiment of the present invention.

### DESCRIPTION OF THE PREFERRED EMBODIMENTS

The description provided below presents the principles of the invention. Therefore, those skilled in the art will be able to devise various apparatuses which, although not explicitly described or shown herein, employ the principles of the invention and fall within the concept and scope of the invention by referring to the following description regarding the principles of the invention. It is also to be understood that all technical terms and embodiments recited in this specification are, in principle, intended only to enable the inventive concept to be understood and are not to be construed as limiting the scope of the invention.

The above and other objects, features and advantages of the present invention will become more apparent from the following detailed description taken in conjunction with the accompanying drawings. Accordingly, those skilled in the art can easily embody the technical ideas of the present invention.

Hereinafter, a biometric sensor according to a first preferred embodiment of the present invention and a display device including the biometric sensor will be described below with reference to the accompanying drawings.

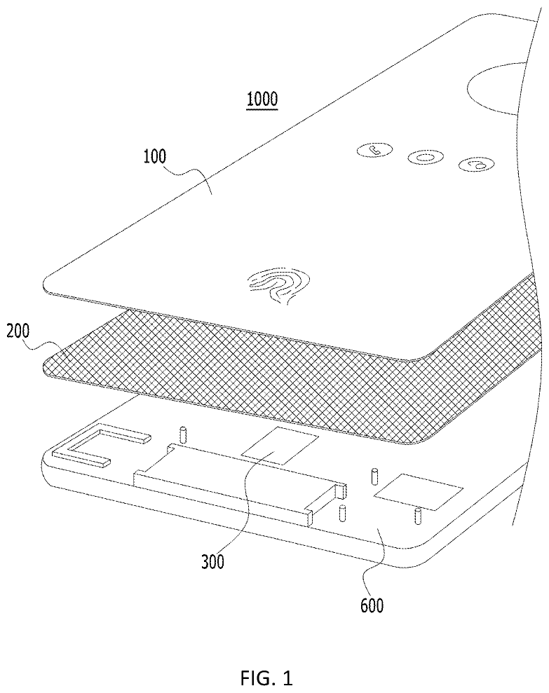

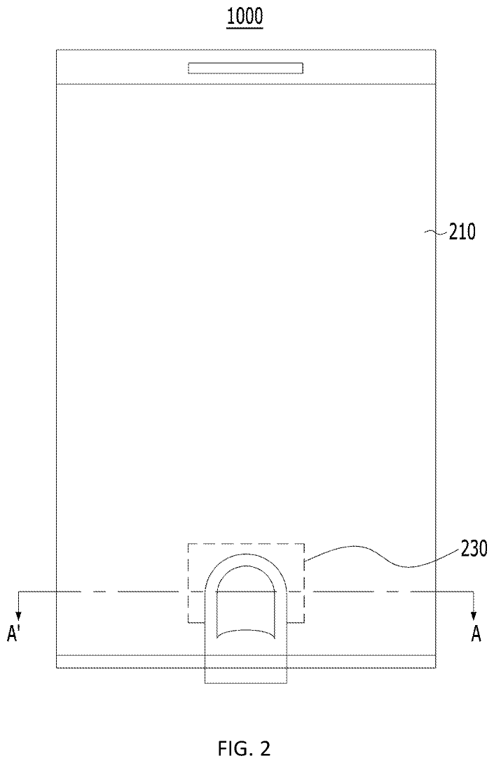

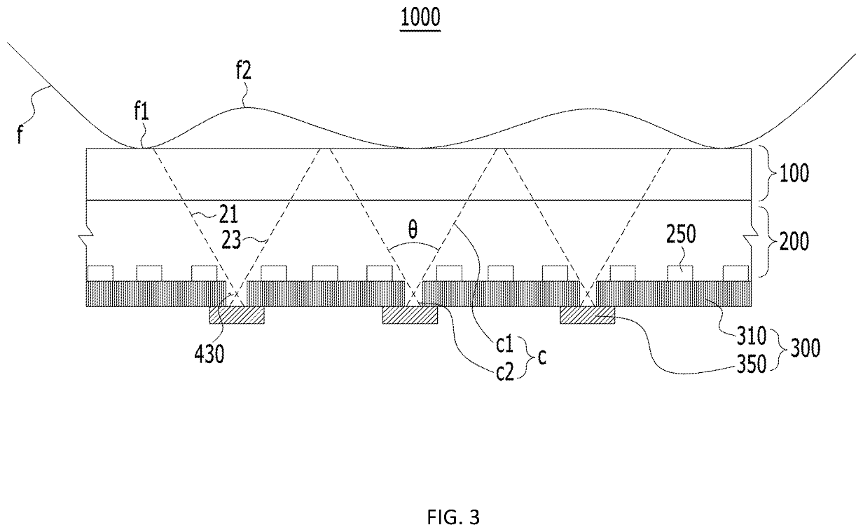

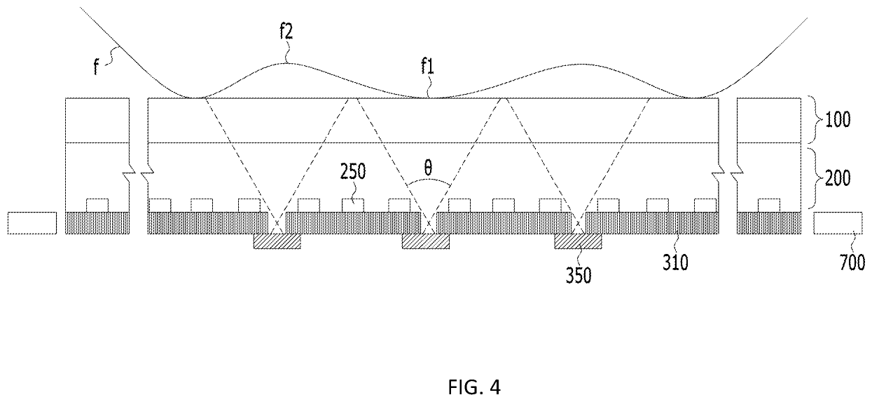

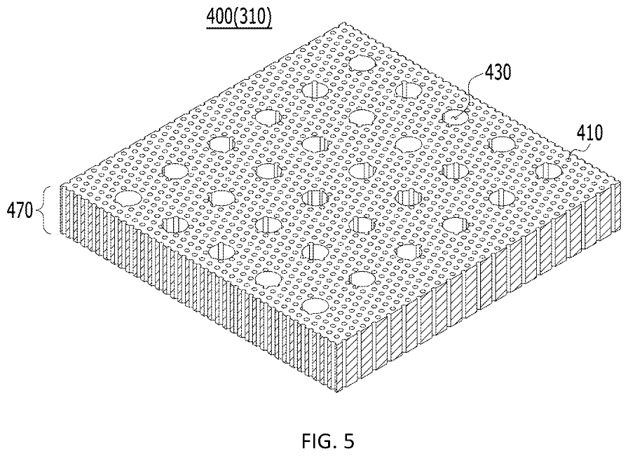

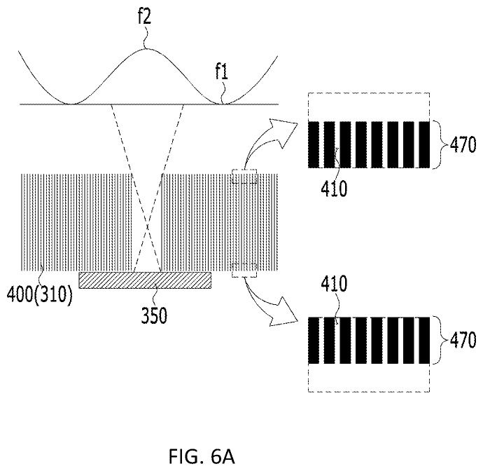

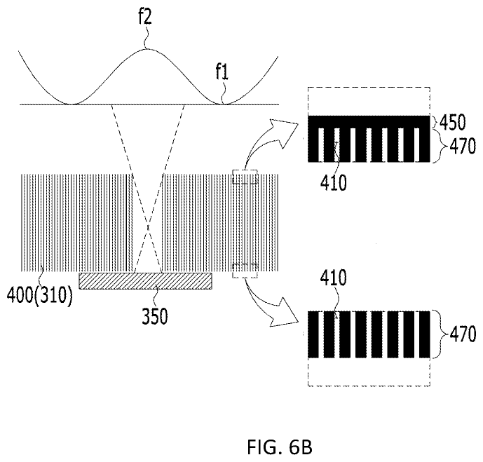

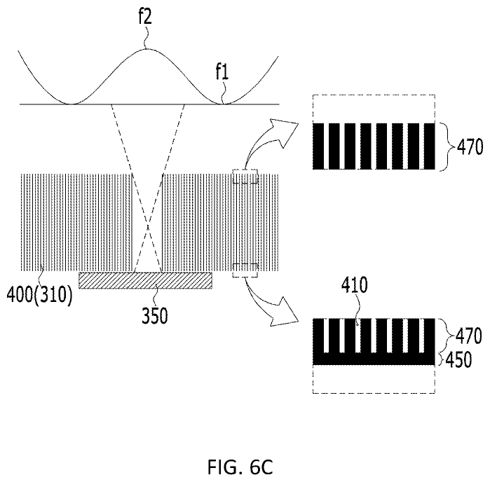

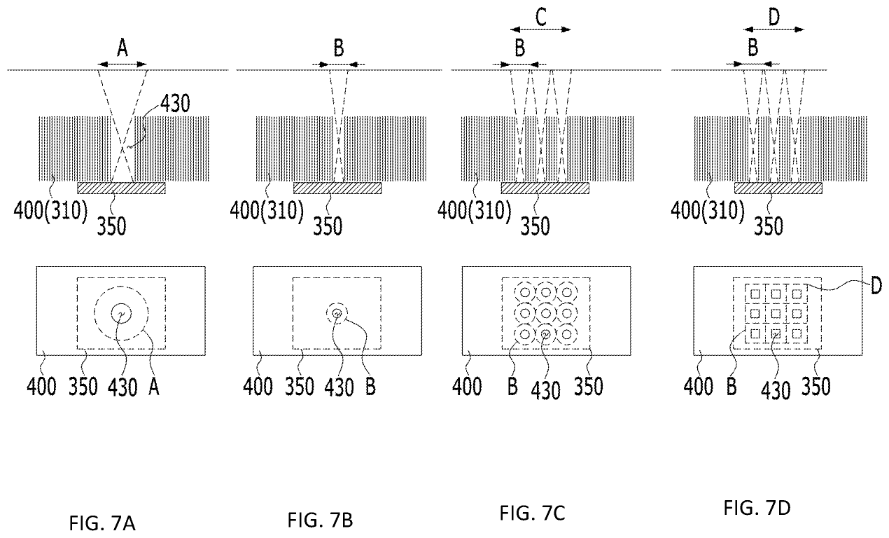

FIG. 1 is an exploded perspective view of a display device having a biometric sensor according to a preferred embodiment of the present invention. FIG. 2 is a plan view of the display device having the biometric sensor according to the preferred embodiment of the present invention. FIG. 3 is a cross-sectional view taken along a line A-A′ of FIG. 2. FIG. 4 is a diagram illustrating a biometric sensor according to a first preferred embodiment of the present invention and a display device having the same. FIG. 5 is a diagram illustrating an anodic oxide film provided in the biometric sensor according to the first preferred embodiment of the present invention and in the display device having the biometric sensor. FIGS. 6A, 6B, and 6C illustrates various forms of the anodic oxide film provided in the biometric sensor according to the first preferred embodiment of the present invention and in the display device having the biometric sensor. FIGS. 7A through 7D illustrates various forms of a through hole in the anodic oxide film provided in the biometric sensor according to the first preferred embodiment of the present invention and in the display device including the biometric sensor.

Referring to FIGS. 1 and 2, according to the first preferred embodiment of the present invention, a display device 1000 includes a front cover 100, a display panel 200 disposed under the front cover 100 and provided with pixels, a biometric sensor 300 disposed under the display panel 200, and a back cover 600. The biometric sensor and the display device having the biometric sensor according to the present invention can be used in various applications.

The display device 1000 including the biometric sensor 300 according to the first embodiment of the present invention may be used for a system having a built-in display panel. Specifically, the display device 1000 may be applied to a system in which the back surface of a display panel 200 transmits a light ray emitted from a light source included in the display panel 200.

The front cover 100 is a member with which a living body (recognition target) comes into contact. The front cover 100 is composed of a transparent substrate made of a light-transmitting material such as tempered glass.

The display panel 200 includes multiple pixels 250. Thus, the display panel 200 emits light having brightness values greater than a reference brightness value through the pixels 250 spatially corresponding to the respective biometric sensors 300. The display panel 200 may display time information thereon. The display panel 200 may include multiple pixels 250 arranged in columns and rows to display an image. Each pixel 250 is configured to emit a light ray of a particular color that constitutes an image. The display panel 200 displays the intended image in a manner that the multiple pixels 250 emit light together. The display panel 1200 may be an LCD display panel, an OLED display panel, or a micro LED display panel. Reference numeral 250 denotes a sub-pixel corresponding to one color such as red, green, or blue or denotes a unit pixel composed of multiple sub-pixels respectively corresponding to red, green, and blue.

Although not illustrated in the drawing, a touch sensor panel is provided. The touch sensor panel and the display panel 200 are separately provided. In this case, the touch sensor panel may be disposed on or under the display panel 200. Alternatively, the touch sensor panel and the display panel 200 may be integrated into a single panel.

The biometric sensor 300 functions to acquire a biometric image. The biometric sensor 300 generates an image signal of a living body (i.e., recognition target) on the basis of light rays that are reflected off from a biometric sampling region placed on the front cover 100 after being emitted from the display panel 200. Herein after, the light rays reflected off from a recognition target will be referred to as “reflection light rays”. As illustrated in FIG. 2, at least part of the recognition target is brought into contact with an interface unit 230 of the display unit 210, the biometric sensor 300 optically acquires an image (for example, fingerprint image) of the living body (recognition target) that is in contact with or is located close to the interface unit 310. In other words, when a fingertip is brought into contact with the interface unit 230 of the display unit 210, the biometric sensor 300 generates and outputs an image signal corresponding to the fingerprint of the fingertip. The biometric sensor 300 may be mounted such that it is fixed to a predetermined area of the back cover 600 of the display device 1000.

The display unit 210 is a screen region within which an intended image will be displayed. Since the interface unit 230 is provided inside the display unit 210, the biometric sensor 300 of the display device 1000 is called an in-screen biometric sensor 300. Alternatively, the biometric sensor 300 may be provided under the display panel 200 of the display device 1000. This biometric sensor 300 is called an under-screen biometric sensor 300.

Referring to FIG. 3, the display panel 200 is disposed under the front cover 100, and the biometric sensor 300 is disposed under the display panel 200. The biometric sensor 300 includes a photo-detector 350 and a collimator 310 that is positioned above the photo-detector 350 to direct a reflection light ray 20 toward the photo-detector 350.

The photo-detector 350 may be a semiconductor layer or a semiconductor chip in which a plurality of photoelectric conversion elements (for example, photodiodes, phototransistors, photogates, or pinned photodiodes) are formed. According to one embodiment of the present invention, the photo-detector 350 may be a semiconductor layer in which an image sensor such as a CMOS image sensor (CIS) or a charge coupled device (CCD) is formed. Preferably, the photo-detector 350 may be a photodiode capable of generating a current signal according to the reflection light ray 20 incident on the photo-detector through the collimator 310.

Each photo-detector 350 senses light rays reflected off from a biometric sampling region and generates an electrical signal corresponding to the sensed light rays. Each photo-detector 350 may generate an electrical signal corresponding to the light rays reflected off from a portion of a living body (for example, the ridge or the valley of a fingerprint). The amount of the reflection light rays sensed by the photo-detector 350 differs between the ridge and the valley of a fingerprint. Thus, electrical signals having different levels are generated according to the amount of the sensed light rays. That is, the electrical signals output from the multiple photo-detectors 350 may include brightness information (or image information). By processing the electrical signals, it is possible to determine whether each biometric sampling region is a ridge or a valley, and it is possible to acquire an overall fingerprint image by combining the information.

The collimator 310 has a through hole 430. The through hole 430 provides an optical path that passes through the collimator 310 from the upper surface to the lower surface and along which a light ray travels to be incident on the photo-detector 350. The optical path through which a light ray can reach the photo-detector 350 has a cone shape having an allowable taper angle determined according to the aspect ratio of the through hole 430. As illustrated in FIG. 3, an optical path through which a light ray can reach the photo-detector 350 has an overall sandglass shape (a pair of cones) composed of an upper corn C1 having a predetermined taper angle θ and a lower cone C2 having a height smaller than that of the upper cone C1 and having the same taper angle θ as the upper cone C1. The photo-detector 350 may detect light rays incident at angles smaller than the taper angle θ of the upper C1.

The collimator 310 may be directly bonded to the photo-detector 350 with no gap therebetween. Alternatively, the collimator 310 may be spaced apart from the photo-detector 350 by a predetermined distance in order to increase an optical sensing area of the photo-detector 350.

The aspect ratio of the through hole 430 limits an optical path range along which light rays can be incident on the bottom of the through hole 430. Thus, only light rays incident at angles smaller than the taper angle θ can be detected. The light rays reflected off from a biometric sampling region pass through the front cover 100 made of a transparent material (i.e., light-transmitting material), the display panel 200, and the through hole 430 of the collimator 310. A light ray having a relatively large incidence angle with respect to the normal line with respect to the photo-detector 35 serving as a reference point cannot reach the photo-detector 350. That is, a light ray having an incidence angle larger than the taper angle θ of the upper cone C1 cannot reach the photo-detector. However, a light ray having a relatively small incidence angle with respect to the normal line (i.e., a light angle having an incidence angle smaller than the taper angle θ of the upper cone C1) can reach the photo-detector 350.

Referring to FIG. 5, the collimator 310 may include an anodic oxide film 400 formed by anodizing a metal (i.e., base material) and then removing the base material (i.e., not anodized portion of the metal). The anodic oxide film 400 refers to a film formed by anodizing a metal and the pores 410 refer to holes formed when anodizing the metal to form the anodic oxide film 400. Each of the through holes 430 extends through the anodic oxide film from the upper surface to the lower surface and provides an optical path enabling light to be incident on the corresponding photo-detector 350.

For example, when the metal serving as a base material is aluminum (Al) or an aluminum alloy, an anodic aluminum oxide (Al₂O₃) as the anodic oxide film 400 is formed on the surface of the base material through anodic oxidation. As described above, the formed anodic oxide film 400 includes a barrier layer 450 having no pores 410 formed therein and a porous layer 470 having the pores 410 formed therein. The barrier layer 450 is disposed directly on the metal (base material) and the porous layer 470 is disposed on the barrier layer 450. After the anodic oxidation is performed, a lower portion (unreacted portion) of the metal (base material) is removed, leaving only the anodic oxide film (i.e., anodic aluminum oxide (Al₂O₃)) 400 including the barrier layer 450 and the porous layer 470. The pores 410 are several to several hundred nanometers wide. FIG. 5 illustrates a state in which the unreacted portion of the base material and the barrier layer 450 are removed and only the porous layer 470 of the anodic oxide film 400 remains.

When the anodic oxide film 400 is etched with a mask provided thereon, vertical through holes 430 corresponding to openings formed in the mask and being perpendicular to the surface of the anodic oxide film 400 are formed. Unlike vertical pores 410 naturally formed in the anodic oxide film 400 during the anodic oxidation, the through holes 430 have a large size. The aspect ratio of the through hole 430 determines an optical path range along which light rays can be incident on the photo-detector.

When the anodic oxide film 400 reacts with an etching solution, the vertical through holes 430 are formed to have a uniform opening size over their full depth. That is, the through holes 430 are uniform in shape over the entire region of the anodic oxide film and have a vertical profile. Therefore, the photo-detectors 350 can reliably detect the reflection light rays 20.

The numerous pores 410 in the anodic oxide film 400 are filled with air. That is, the anodic oxide film 400 have numerous air columns. Therefore, when the reflection light rays 20 are incident on the periphery of a certain through hole 430 from the outside of a corresponding light incidence range determined by the aspect ratio of the through hole 430, the numerous air columns formed around the through hole 430 cause total reflection of the obliquely incident reflection light rays, thereby preventing the obliquely incident reflection light rays from entering into the through hole 430.

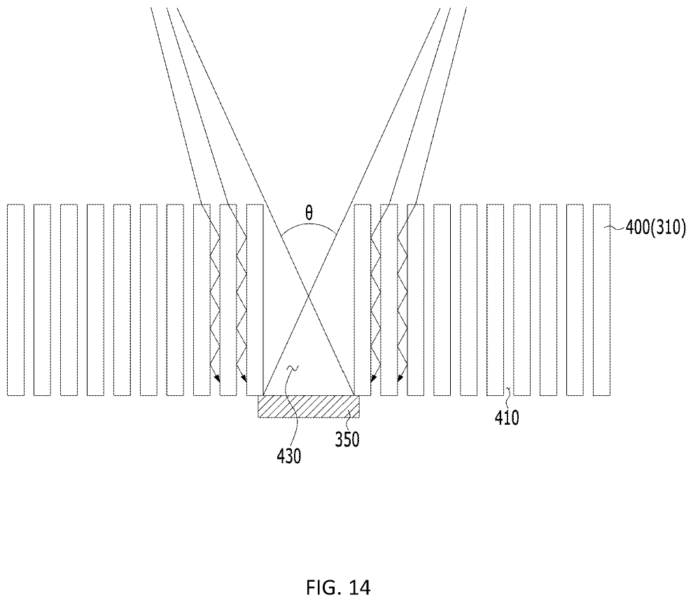

Further details of the display device will be described below with reference to FIG. 14. When reflection light rays starting from a position inside a light incidence range determined by the aspect ratio of the through hole 430 enters a certain through, the reflection light rays can reach the corresponding photo-detector 350. However, reflection light rays starting from a position outside the light incidence range determined by the aspect ratio of the through hole 43 cannot not enter the through hole due to the total refection caused by the numerous pores (i.e., air columns).

Therefore, it is possible to prevent the reflection light rays incident from the outside of the light incidence range determined by the aspect ratio of the through hole 430 from being mixed with the reflection light rays incident from the inside of the light incidence range determined by the aspect ratio of the through hole 430. Therefore, each of the photo-detectors 350 can obtain clear biometric image information of a biometric sampling region placed immediately above the photo-detector 350.

The thermal expansion coefficient of the anodic oxide film 400 is 2 to 3 ppm/° C. Therefore, thermal deformation of the through holes 430 due to an ambient heat rarely occurs. Therefore, the aspect ratio of the through holes 430 does not change, which prevents the reliability in the biometric recognition from being degraded due to thermal deformation of the through holes 430.

FIGS. 6A, 6B, and 6C illustrates various forms of the anodic oxide film 400. As illustrated in FIG. 6A, the pores 410 may be open at their upper and lower ends, i.e., in both the upper and lower surfaces of the anodic oxide film 400. Alternatively, as illustrated in FIG. 6B, the pores 410 are closed at their upper end by the barrier layer 450 provided on the upper surface of the anodic oxide film 400 and are open only at their lower end in the lower surface of the anodic oxide film 400. Further alternatively, as illustrated in FIG. 6C, the pores 410 are closed at their lower end by the barrier layer 450 provided on the lower surface of the anodic oxide film 400 and are open only at their upper end in the upper surface of the anodic oxide film 400.

Referring to FIGS. 7A to 7D, various forms of the through hole 430 will be described. As the aspect ratio of the through hole 430 is increased, a light receiving region of the photo-detector 350 is decreased. For example, the through hole 430 in FIG. 7A and the through hole 430 in FIG. 7B have the same depth but different widths. The width of the through hole 430 in FIG. 7A is larger than that of the through hole 430 in FIG. 7B. Thus, biometric sampling regions A and B within which reflection light rays can be incident on the bottom of the through holes 430 are smaller than the biometric sampling region B of FIG. 7B. Therefore, as the aspect ratio of the through holes 430 is increased, it more effectively prevents the mixing of reflection light rays 20.

Referring to FIG. 7C, multiple through holes 430 are provided on one photo-detector 350. Preferably, the biometric sampling region B for one through hole 430 does not overlap the biometric sampling region B for an adjacent through hole 430. With this arrangement of the through holes 430, each photo-detector 350 can detect a clear fractional biometrical image corresponding to a measurement target region.

Referring to FIG. 7D, the through hole 430 has a rectangular cross-sectional shape unlike the through hole 430 having a circular cross-sectional shape illustrated in FIG. 7C. Referring to FIG. 7C, the biometric sampling region B within reflection light rays can be incident on the bottom of the through hole 430 has a circular shape. Therefore, a large dead zone is present between adjacent biometric sampling regions B. However, in the case of FIG. 7D, since the biometric sampling regions within which reflection light ray can be incident on the bottom of the respective through holes 430 have a rectangular cross-sectional shape, a very small dead zone or no dead zone exists between the adjacent biometric sampling regions B. In this case, since the biometric sampling regions B are densely defined, it is possible to obtain a larger number of fractional biometric images respectively corresponding to measurement target regions, thereby obtaining a higher resolution biometric image by combining the larger number of fractional biometric images. The cross-sectional shape of the through holes 430 is not limited to a rectangular shape but it may be any polygon shape or an oval shape.

The anodic oxide film 400 employed as the collimator 310 contains a light-absorbing material, thereby enabling the reflection light rays 20 to be directed toward the photo-detectors 350 only through the through holes 430. In addition, a substantially black anodic oxide film 400 may be manufactured by adding a block component such as manganese salts or molybdenum salts to an electrolyte solution when anodizing a metal (base material) to prepare the anodic oxide film. Alternatively, a substantially black anodic oxide film 400 may be produced in a manner that a non-black anodic oxide film is first prepared and then the prepared anodic oxide film is dyed. Any method that can impart the light-absorbing ability to the anodic oxide film 400 may be used.

The anodic oxide film 400 employed as the collimator 310 has a light-absorbing layer formed on at least one of the upper and lower surfaces of the anodic oxide film, thereby enabling the reflection light rays 20 to be directed toward the photo-detectors 350 through the through holes 430. The material of the light-absorbing layer is not particularly limited as long as it can absorb reflection light rays passing a position outside the optical path range of the through hole 430. The inner surface of the through hole 430 of the anodic oxide film 400 employed as the collimator 310 may be provided with the above-described light-absorbing layer. The light-absorbing layer formed on the inner surface of the through hole 430 prevents crosstalk between the photo-detectors 350 adjacent to each other by absorbing reflection light lays that obliquely enter at an incidence angle larger than the taper angle θ Of the upper cone C1.

The anodic oxide film 400 employed as the collimator 310 has a light-shielding layer on at least one of the upper surface and the lower surface thereof, thereby enabling the reflection light rays 20 to travel toward the photo-detectors 350 only through the through holes 430. The light-shielding layer may be made of any material that can block reflection light rays entering from a position outside an optical path range of the through hole 430.

The inner surface of the through hole 430 formed in the anodic oxide film 400 employed as the collimator 310 is coated with the light-absorbing layer, the light-shielding layer, or both.

Referring back to FIG. 3, the through hole 430 is positioned between the pixels 250 and under the display panel 200. The display panel 200 is configured such that a predetermined number of sub-pixels 250 constitute a pixel serving as a basic unit for expressing a piece of an image, to display the intended image. For example, as illustrated in FIG. 3, three sub-pixels 250 constitute one pixel. The through hole 430 of the collimator 310 is formed to have a size determined according to the pitch of the pixels. That is, the through hole 430 is formed to be disposed between the pixels of the display panel.

The display panel 200 may include supports (not illustrated) that support the respective pixels. The supports are made of a light-transmitting material or have holes at the positions corresponding to the through holes 430. Due to the presence of the light-transmitting material or the holes corresponding to the through holes 430, it is possible to improve the detection performance of the biometric sensor. By employing the structure described above, it is possible to implement a display device 1000 having an in-screen biometric sensor 300 or an under-screen biometric sensor 300.

The display panel 200 normally represents an image thereon through the pixels 250 in such a manner that the pixels 250 output their fractional images to the display unit 210. However, when obtaining a biometric image, the pixels 250 emit emission light rays 10. The light rays 10 emitted from the pixels 250 of the display panel 200 are reflected off from a recognition target (living body), and only substantially perpendicular reflection light rays among the total reflection light rays are directed toward the photo-detectors 350 through the collimator 310. Thus, each of the photo-detectors 350 detects only a piece of the recognition target, which is positioned directly above the photo-detector 350, and generates a fractional image. The fractional images generated by the photo-detectors 350 are combined to form the whole biometric image of the living body (recognition target). Therefore, the resolution of the biometric image of the recognition target is dramatically improved.

Referring to FIG. 4, aside from the pixels 250 of the display panel 200, a light source 700 may be additionally provided. The light source 700 is provided under a peripheral area of the display panel 200. Light rays emitted from the light source 700 are reflected off from a living body, and only substantially perpendicular reflection light rays among the reflection light rays are directed toward the photo-detectors 350 through the collimator 310. The light source 700 includes a light-emitting diode (LED).

Hereinafter, biometric sensors according to second and third preferred embodiments of the present invention and display devices having the respective biometric sensors will be described in detail with reference to the accompanying drawings.

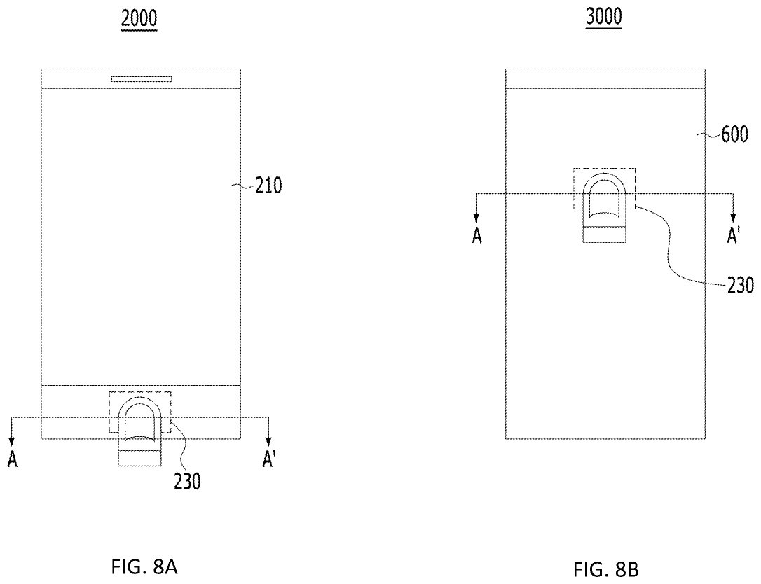

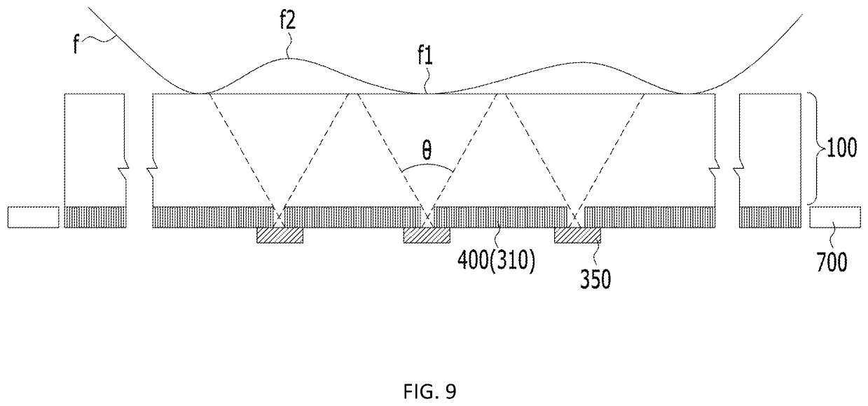

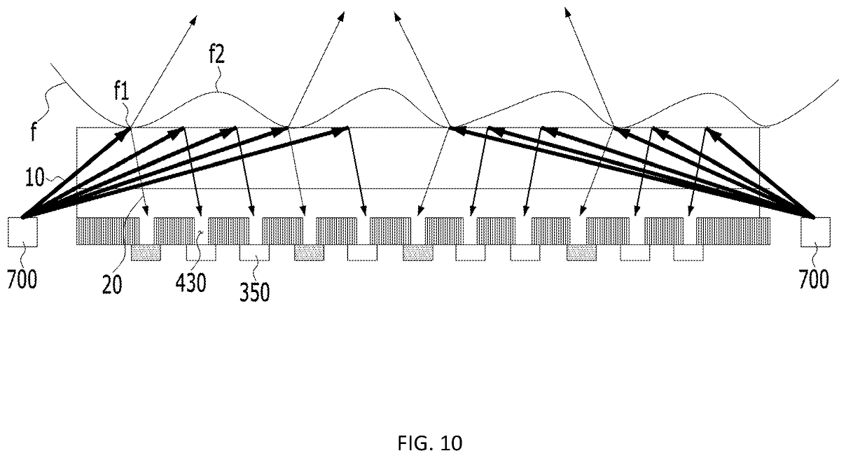

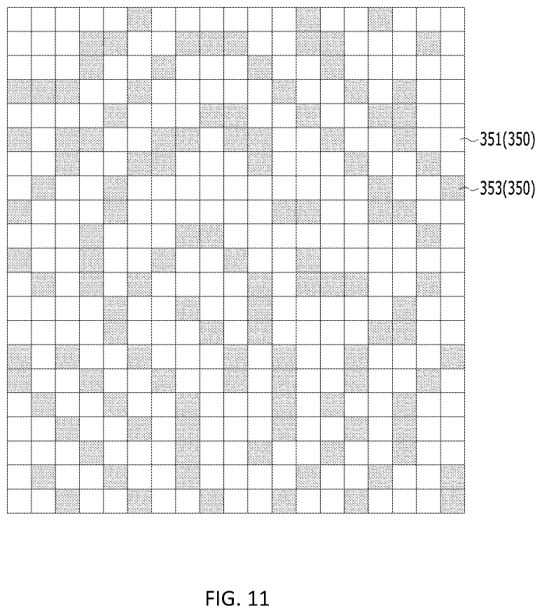

FIGS. 8A and 8B are plan views illustrate the biometric sensors and the display devices according to the second and third embodiments. FIG. 9 is a cross-sectional view taken along a line A-A′ of FIGS. 8A and 8B. FIG. 10 is a diagram illustrating emission light rays and reflection light rays occurring in the biometric sensors and the display devices according to the second and third embodiments of the present invention. FIG. 11 is a digitized form of an overall image of a living body (recognition target) generated by the photo-detectors of the biometric sensors and the display devices according to the second and third embodiments.

Referring to FIG. 8A, a display device 2000 including a biometric sensor according to the second embodiment of the present invention includes: a front cover 100 made of a light-transmitting material; a biometric sensor 300 disposed under the front cover 100 and including a collimator 310 configured to direct reflection right rays toward photo-detectors 350 and the photo-detectors 350 configured to detect the reflection light rays collimated by the collimator 310; and a light source 700 provided on a side surface of the biometric sensor 300. The light source 700 includes a light-emitting diode (LED).

The display device 2000 including the biometric sensor according to the second embodiment of the present invention differs from the display device according to the first embodiment in that the display panel 200 is not provided on the biometric sensor 300 and that the light source 700 is additionally provided on the side surface of the biometric sensor 300. A further different point is that the interface unit 230 is separate from the display unit 210 in the second embodiment but the interface unit 230 is provided in the display unit 210 in the first embodiment.

Referring to FIG. 8B, a display device 3000 including the biometric sensor according to the third embodiment of the present invention includes: a back cover 600 made of a light-transmitting material; a biometric sensor 300 disposed under the back cover 600 and including a collimator 310 configured to direct reflection right rays toward photo-detectors 350 and the photo-detectors 350 configured to detect the reflection light rays collimated by the collimator 310; and a light source 700 provided on a side surface of the biometric sensor 300. The light source 700 includes a light-emitting diode (LED).

The display device 3000 including the biometric sensor according to the third embodiment of the present invention differs from the display device according to the first embodiment in that the display panel 200 is not provided on the biometric sensor 300 and that the light source 700 is additionally provided on the side surface of the biometric sensor 300. A further different point is that the interface unit 230 is provided on the back surface of the display device so as to be separated from the display unit 210 in the third embodiment but the interface unit 230 is provided in the display unit 210 in the first embodiment.

As illustrated in FIG. 9, in the display devices including the respective biometric sensors according to the second and third embodiments, the light source 700 is provided on the side surface of the biometric sensor 300, thereby generating oblique light rays 10. Referring to FIG. 10, when the light rays obliquely emitted from the light source 700 meet the ridges f1 of a fingerprint f of a fingertip, a portion of the light rays enter into the fingertip and the remaining portion of the light rays reflect off from the ridges f1 and change their direction toward the biometric sensor 300. Herein, the light rays emitted from the light source 70 will be referred to as “emission light rays” and the light rays that are reflected off from the fingerprint will be referred to as “reflection light rays”. On the other hand, when the emission light rays 10 meet the valleys f2 of the fingerprint f, the emission light rays 10 become the reflection light rays 20, and the reflection light rays 20 are directed toward the biometric sensor 300. When the ridge f1 is positioned directly above a certain photo-detector 350, the amount of light rays reaching the photo-detector 350 is decreased in comparison with the amount of emission light rays. Therefore, the photo-detector 350 causes a weak electric current. On the other hand, when the valley f2 is positioned directly above a certain photo-detector 350, the amount of light rays reaching the photo-detector 350 does not change. Therefore, the photo-detector 350 causes a relatively strong electric current.

That is, the photo-detectors 35 generate electrical signals of different current levels depending on which part of the fingerprint between the ridge f1 and the valley f2 is placed thereon. According to the electrical signals generated by the respective photo-detectors 350, fractional fingerprint images are generated and then converted into digitized forms. Thus, a digitized fingerprint image illustrated in FIG. 11 is obtained. That is, only a fraction of a living body disposed directly above each photo-detector 350 can be detected by the corresponding photo-detector 350, and the resulting fractional images are integrated into an overall biometric image. In this way, it is possible to obtain a high-resolution biometric image.

The mounting position of the biometric sensor 300 is not limited to the examples described above. The biometric sensor 300 may be mounted on the upper surface or the side surface of the display device 1000, 2000, or 3000, or on a power button provided on the side surface of the display device 1000, 2000, or 3000.

Hereinafter, a biometric sensor according to a fourth preferred embodiment of the present invention and a display device having the biometric sensor will be described in detail with reference to the accompanying drawings.

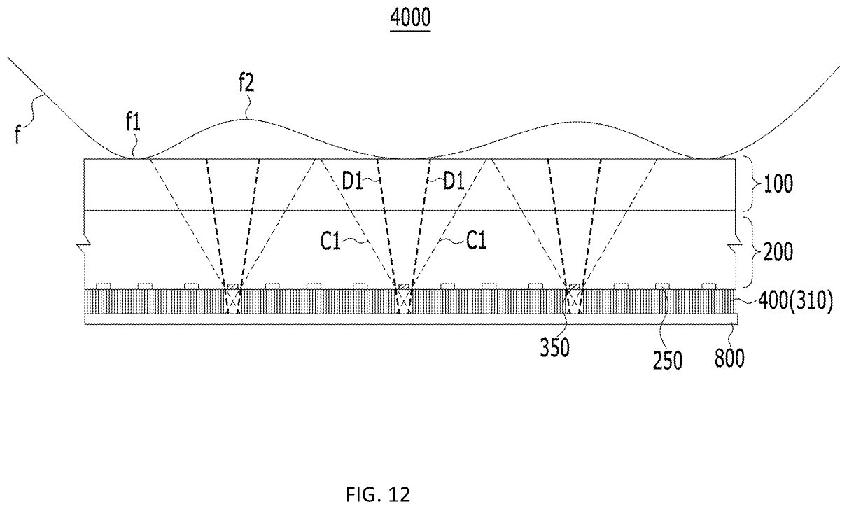

FIG. 12 is a diagram illustrating a biometric sensor according to a fourth embodiment of the present invention and a display device including the biometric sensor.

The display device 4000 including the biometric sensor according to the fourth embodiment of the present invention differs from the display devices according to the first through third embodiments of the present invention in that the anodic oxide film 400 is disposed on the photo-detectors 350 in the display devices according to the first through third embodiments but an anodic oxide film is disposed on photo-detectors 350 and a reflective layer 800 is additionally provided under through holes 430 of the anodic oxide film 430. The other constituents of the display device according to the fourth embodiment of the present invention are the same as the display devices according to the other embodiments of the present invention. Due to the presence of the reflective layer 800, the photo-detectors 350 detect light rays reflected off from the reflective layer 800 after traveling through the through holes 430.

The reflective layer 800 is configured to reflect light rays. The reflective layer 800 is configured to close only the lower ends of the respective through holes 430 or is formed on the entire lower surface of the anodic oxide film 400. The reflective layer 800 may be a uniform thickness layer. Alternatively, the reflective layer 800 may have hemispherical convexes positioned to correspond to the through holes 430, thereby focusing the light rays introduced into each of the through holes 430 and reflecting the focused light beams toward the corresponding photo-detectors 350.

The inner surface of each of the through holes 430 is coated with a light-absorbing layer (not illustrated). The light-absorbing layer on the inner surface of each of the through holes 430 absorbs light reflected to be incident thereon, thereby constricts the optical path range along which light rays can be incident onto the corresponding photo-detector 350 to a region in the vicinity of the normal line of the photo-detector 350.

The photo-detectors 350 may be disposed to be flush with the pixels 250 of the display panel 200 or disposed on a plane having a height difference from a plane on which the pixels 250 of the display panel 200 are arrayed. FIG. 12 illustrates an example in which the photo-detectors 350 are substantially flush with the pixels 250 of the display panel 200.

With the arrangement in which the photo-detectors are disposed on the anodic oxide film 400, each of the photo-detectors 350 can detect reflection light rays having a small incident angle, which enter closely to the normal line of the photo-detector 350. In FIG. 12, reference character C1 denotes an optical path range along which light rays can be incident on the photo-detector 350 when the photo-detector 350 is disposed under the anodic oxide film 400, reference character D1 denotes an optical path range along which light rays can be incident on the photo-detector 350 when the photo-detector 350 is disposed on the anodic oxide film 400. As illustrated in FIG. 12, the structure in which the photo-detector 350 is disposed on the anodic-oxide film 400 has a smaller optical path range than the structure in which the photo-detector 350 is disposed under the anodic-oxide film 400. As the optical path range is decreased, it is possible to clearer fractional biometric images by preventing light mixing between the photo-detectors 350 adjacent to each other.

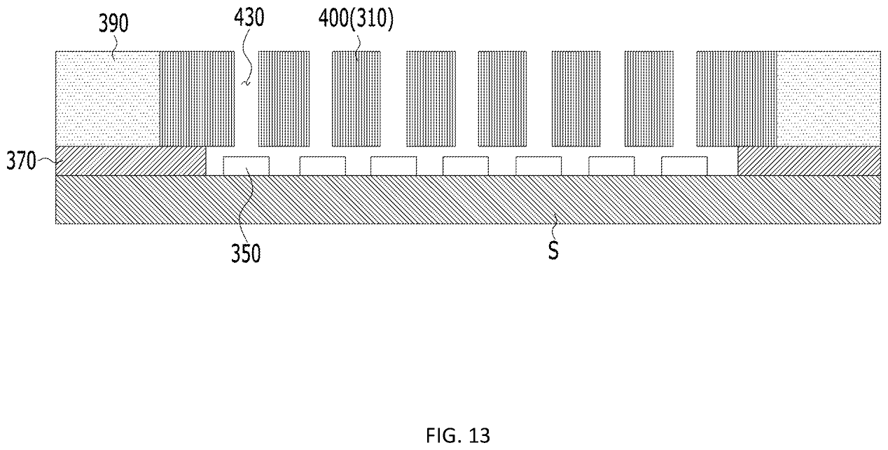

FIG. 13 is a diagram illustrating the structure of a biometric sensor package according to one embodiment of the present invention. Referring to FIG. 13, since a biometric sensor package is attached to the lower surface of the display panel 200, the display device 1000 has an in-screen biometric sensor structure and an under-screen biometric sensor structure in which the biometric sensor 300 is disposed under the display panel 200.

Referring to FIG. 13, the display device includes the anodic-oxide film 400 having the through holes 430, the photo-detectors 350 disposed under the anodic-oxide film 400, a substrate S that supports the photo-detectors 350 and is provided with wiring lines, a bonding region 390 provided on a side surface of the anodic-oxide film 400, and a support 370 that supports the anodic-oxide film 400 in a suspended manner. The photo-detectors 350 are disposed under the through holes 430, thereby detecting a change in the amount of reflection light rays introduced through the corresponding through holes 430 and incident thereon.

The bonding portion 390 functions to bond the biometric sensor package to the display panel 200. The bonding portion 390 may include an adhesive film or a liquid adhesive. The bonding portion 390 may be prepared by forming an elevated portion and providing an adhesive film or a liquid adhesive to the upper surface of the elevated portion.

The support 370 supports the anodic-oxide film 400 and/or the bonding portion 390, with the lower surface of the anodic-oxide film 400 spaced from the upper surfaces of the photo-detector 350. This structure prevents the upper surfaces of the photo-detectors 350 from undergoing thermal deformation due to the difference in thermal expansion coefficient between the substrate supporting the photo-detectors 350 and the anodic-oxide film 400. In the case where the inner surface of each of the through holes 430 is coated with a light-absorbing layer (not illustrated), the biometric sampling region is reduced due to the gap between the upper surface of the photo-detector 350 and the lower surface of the anodic-oxide film 400. Therefore, it is possible to more densely define the biometric sample regions provided directly above the photo-detectors 350.

At the position at which the bonding portion 390 is provided, a light source (not illustrated) may be provided instead of the bonding portion 390. That is, the side surface of the anodic oxide film 400 may be provided with a light source. By adopting the structure described above, it is possible to form a biometric package applicable to the display devices 2000 and 3000 according to the second and third embodiments.

Although preferred embodiments of the present invention have been described above, the ordinarily skilled in the art will appreciate that various changes and modifications to the claimed invention without departing from the scope or spirit of the present invention defined in the appended claims.

What is claimed is:

1. A biometric sensor comprising:
a photo-detector; and
an anodic oxide film provided with a through hole vertically extending through the anodic oxide film from an upper surface to a lower surface, having a larger width than pores formed in the anodic oxide film during anodic oxidation, and providing an optical path leading to the photo-detector.

2. The biometric sensor according to claim 1, wherein the anodic oxide film contains a light-absorbing material, thereby enabling a light ray to travel toward the photo-detector only through the through hole.

3. A display device comprising:
a display panel provided with pixels; and
a biometric sensor including a photo-detector and a collimator,
wherein the collimator comprises an anodic oxide film provided with a through hole vertically extending through the anodic oxide film from an upper surface to a lower surface, having a larger width than pores formed in the anodic oxide film during anodic oxidation, and providing an optical path leading to the photo-detector.

4. The display device according to claim 3, wherein the through hole is positioned between the pixels and under the display panel.

5. The display device according to claim 3, further comprising a light source provided on a side surface of the biometric sensor and configured to emit an emission light ray.

6. The display device according to claim 5, wherein the light source is a light emitting diode (LED).

7. The display device according to claim 3, wherein a biometric sampling region within which a light ray can be incident on the bottom of the through hole does not overlap with a biometric reflection region within which a light ray can be incident on the bottom of an adjacent through hole.

8. The display device according to claim 3, wherein the through hole has a rectangular cross-sectional shape.

9. The display device according to claim 3, wherein the photo-detectors and the through holes are in a one-to-multiple correspondence relationship.

10. The display device according to claim 5, wherein the biometric sensor is a fingerprint recognition sensor.

11. The display device according to claim 3, wherein the anodic oxide film is disposed on the photo-detector.

12. The display device according to claim 3, wherein the anodic oxide film is disposed under the photo-detector.

13. A display device comprising:
a front cover made of a light-transmitting material;
a display panel disposed under the front cover and provided with pixels; and
a biometric sensor disposed under the display panel,
wherein the biometric sensor includes a photo-detector and a collimator disposed on the photo-detector and configured to direct a reflection light ray toward the photo-detector,
wherein the collimator comprises an anodic oxide film provided with a through hole vertically extending through the anodic oxide film from an upper surface to a lower surface, having a larger width than pores formed in the anodic oxide film during anodic oxidation, and providing an optical path leading to the photo-detector.

14. The display device according to claim 13, further comprising a light source provided on a side surface of the biometric sensor and configured to emit an emission light ray.
